(19) United States
(12) Patent Application Publication
(10) Pub. No.: US 2014/0368085 A1
(43) Pub. Date: Dec. 18, 2014

(54) Piezoelectric Component and Method for Producing a Piezoelectric Component

(71) Applicant: EPCOS AG, Muenchen (DE)

(72) Inventors: Franz Rinner, Deutschlandsberg (AT); Dieter Somitsch, Gross St. Florian (AT)

(21) Appl. No.: 14/362,352

(22) PCT Filed: Nov. 7, 2012
(86) PCT No.: PCT/EP2012/072057

§ 371 Date: Jun. 2, 2014

(30) Foreign Application Priority Data
Dec. 2, 2011 (DE) 10 2011 055 996.5

(51) Int. Cl. H01L 41/053; H01L 41/25; H01L 41/083

(52) U.S. Cl. CPC H01L 41/0533; H01L 41/083; H01L 41/25
USPC 310/344; 29/17.3

(57) ABSTRACT

A piezoelectric component includes a main body, which is surrounded at least in part by an enclosure for protecting the main body. The enclosure includes a structured foil. A method for producing a component of this type is also specified, in which a main body of the component and a structured foil are provided. The structured foil is then wound around the main body.

This patent application is a national phase filing under section 371 of PCT/EP2012/072057, filed Nov. 7, 2012, which claims the priority of German patent application 10 2011 055 996.5, filed Dec. 2, 2011, each of which is incorporated herein by reference in its entirety.

### TECHNICAL FIELD

A piezoelectric component is specified that is formed, by way of example, as a piezo actuator. A piezo actuator can be used to actuate an injection valve in a motor vehicle.

### BACKGROUND

German Publication No. 10 2006 006 076 A1 describes a piezo actuator that has an enclosure. U.S. Patent Application Publication No. 2010/0180865 A1 describes a piezo actuator that is provided with a multi-layer coating.

### SUMMARY OF THE INVENTION

Embodiments specify a piezoelectric component that has high reliability. Further embodiments a method for producing a component of this type.

A piezoelectric component having a main body is specified. The main body is surrounded at least in part by an enclosure that comprises a structured foil. The enclosure is preferably configured to protect the main body.

By way of example, the component is formed as a piezo actuator, in particular as a piezo actuator for actuating an injection valve in a motor vehicle. The enclosure is preferably formed as a moisture barrier, such that the main body is protected against the infiltration of moisture and against the infiltration of harmful chemicals.

The component is preferably formed as a multi-layer component. In particular, the main body may have a plurality of piezoelectric layers arranged one above the other and electrode layers arranged therebetween. The main body is formed as a monolithic sintered body, by way of example.

The main body preferably extends along a longitudinal axis. When a voltage is applied between adjacent electrode layers, the main body preferably expands. By way of example, the direction of expansion coincides with a longitudinal axis of the main body. Here, the direction of expansion is preferably the direction along which the main body expands to the greatest extent when a voltage is applied.

The structuring of the foil is preferably formed in such a way that mechanical stresses in the foil are kept low.

Mechanical stresses of this type, in particular expansion stresses, can occur, for example, with an expansion of the component when an electric voltage is applied. Furthermore, mechanical stresses may be created in the event that cracks form in the component, in particular cracks in the main body. A crack can occur, for example, during polarization of the piezoelectric component or during operation of the component.

Here, cracks can form particularly easily in a main body that has an inactive region, in which electrode layers adjacent in the stack direction do not overlap one another. By way of example, the electrode layers are guided alternately in the stack direction as far as an outer face of the main body and are distanced from the opposite outer face. When a voltage is applied between adjacent outer electrodes, the main body expands in the active region, in which adjacent electrode layers overlap one another. In the inactive region, the expansion is much smaller or is absent. Mechanical stresses may occur due to the different expansion. These stresses can lead to a partial delamination of the component. In particular, cracks can form on the outer face of the main body, in particular between adjacent piezoelectric layers. Here, local stress peaks may occur at the outer face of the main body. Stress peaks of this type may lead to an overexpansion of the enclosure, in particular of the foil, and to the formation of a crack in the enclosure.

The structuring of the foil is preferably formed in such a way that the formation of cracks in the foil is prevented. By way of example, the mechanical stresses occurring in the foil can be kept low due to the structuring. In particular, the foil can be structured in such a way that, with an expansion of the main body and with expansion forces acting on the enclosure during this process, the foil merely deforms, however mechanical stresses in the foil are kept low. Forces occurring in the foil can thus be taken up by a deformation of the foil, without the formation of a crack in the foil.

The structured foil is preferably a metallic foil or a metal foil. By way of example, the foil comprises aluminum, and in particular the foil can be formed as an aluminum foil. The foil is preferably sufficiently thin, such that it can be wound around the main body of the component.

The structuring of the foil is preferably a three-dimensional structuring of the foil, in particular a surface-structuring of the foil. The structuring of the foil is preferably formed before the foil is arranged on the main body of the component, in particular is wound around the main body.

The foil preferably has at least one indentation or elevation. The indentation or elevation of the foil is formed in such a way that, when expansion forces occur in the foil, the foil is deformed in the indentation or elevation thereof. By way of example, the indentations or the elevations in the foil are flatter when expansion forces are applied. When compression forces occur the indentations or elevations can become deeper or taller respectively.

By way of example, the indentation or elevation expands three-dimensionally in a direction perpendicular to the direction of expansion of the component.

The indentation or elevation preferably runs over an entire side of the main body, in particular over a width of the main body. The indentation or elevation particularly preferably runs around the entire periphery of the main body. In one embodiment the main body has a longitudinal axis. By way of example, the indentation or elevation extends perpendicularly to the longitudinal axis of the main body. The longitudinal axis can coincide with the direction of expansion. The indentation is formed as a groove, by way of example. The elevation is formed as a rib, by way of example.

In a further embodiment the indentation or elevation is formed in such a way that excessively strong expansion stresses in the foil can be prevented in a number of spatial directions. In particular, expansion forces directed in different directions can be taken up by a deformation of the foil. By way of example, the foil is formed in such a way that expansion forces can be compensated for both along the longitudinal axis and perpendicularly to the longitudinal axis by a deformation of the foil. By way of example, the elevation or indentation can be dented, and in particular may have a circular periphery.

The foil preferably has a plurality of indentations or elevations.

By way of example, a plurality of indentations or elevations are arranged along the direction of expansion. Each indentation or elevation preferably has the same form. By way of example, the elevations are formed as ribs, each of which may run perpendicularly to the direction of expansion. The foil may thus have a ribbed structure. The elevations may also run in an undulating manner, for example, the elevations can be formed as wave crests. The indentations can be formed as wave troughs.

At least one surface region of the foil is preferably arranged at an angle between 40° and 60° to an outer face of the main body.

This angle may also be referred to as the aperture angle α of the surface region of the foil. Expansion peaks can thus be taken up particularly well by a three-dimensional deformation of the foil, without the formation of stresses in the foil. When expansion forces occur, merely the aperture angle preferably changes. In particular, the aperture angle is between 40° and 55° in an undeformed state. It has been found that, with such an angle, a mechanical loading of the foil can be kept particularly low. In particular, an angle from 45° to 50° has proven to be expedient with formation of a poling crack in the main body.

The foil is preferably wound around the main body of the component.

In particular, the foil may be flat before the winding process, apart from its indentations or elevations, and may thus run in a main plane. Only when wound around the main body does the foil preferably obtain a form adapted to the main body, for example, a cylinder form.

The foil is preferably wound around the main body in such a way that at least the outer lateral surface of the main body is enclosed completely by the foil. The main body is preferably cylindrical. In particular, the main body may have a cuboid form.

In an embodiment the enclosure is multi-layered. By way of example, the foil is wound a number of times around the main body.

A number of layers of the foil can thus be arranged one above the other. The layers are preferably arranged one above the other in such a way that no air bubbles are present in the enclosure. In particular, the foil can be wound around the main body in low-pressure or vacuum conditions.

In one embodiment an insulating material is arranged on at least one side of the foil.

In particular the insulating material is an electrically insulating material. By way of example, the insulating material comprises an organic material. The insulating material does not have to be arranged over the entire side of the foil, but can also be provided only in certain regions.

The insulating material is preferably applied to a side of the foil facing the main body.

The insulating material preferably completely fills the space between the foil and the main body. In particular, the insulating material is arranged in a form-fitting manner on the foil and on the main body.

In a further embodiment the insulating material is arranged on a side of the foil facing away from the main body. In particular, the insulating material may be provided on an outer face of the enclosure. The insulating material is preferably applied in such a way that the enclosure has a smooth outer surface.

Furthermore, the insulating material may also be arranged on the foil on both sides.

The insulating material is preferably resilient. The insulating material is preferably sufficiently thick between the main body and the foil so that it can distribute any expansion peaks occurring and these are not transmitted in an unchanged manner to the foil.

To optimize the structuring of the foil, a global expansion approach can be adopted, by way of example. Here, it is assumed that the insulating material is deformable and incompressible, such that the volume of the insulating material is constant. Furthermore, the foil is merely to deform, without expansion of the foil. In the case of an expansion of the main body, the main body is expanded in one direction and tapers in a direction perpendicular thereto. With this approach, an aperture angle α of surface regions in an elevation, in particular a rib-shaped elevation, in a range between 48° and 53° has proven to be particularly advantageous. In particular, the aperture angle should preferably be greater than 45°. With the global expansion approach, the optimal aperture angle can be calculated, for example, from the piezoelectric constants for the transverse expansion d31 and for the longitudinal expansion d33 of the component in accordance with the following formula:

tan α=\sqrt{1/(1−η)}, with η=d31/d33.

By way of example, η ranges from 0.3 to 0.4.

In one embodiment the foil has a fastening region, which is arranged above a further region of the foil and is fastened to this region. The foil is preferably soldered in its fastening region to the foil region arranged therebeneath. The fastening region is formed, for example, by a lateral-side edge region of the foil extending along the outer lateral surface. The enclosure can thus be sealed along the outer lateral surface.

In one embodiment the component has at least one end piece, which is arranged at one end of the main body. The enclosure is preferably fastened to the end piece. In particular, the enclosure is connected continuously and fixedly to the end piece, such that no moisture can infiltrate at the longitudinal-side ends of the enclosure.

By way of example, the end piece is a ceramic body. The end piece is preferably fastened to the main body, for example, adhesively bonded to the main body. The main body preferably has two end pieces, which are arranged on the longitudinal-side ends of the main body. The enclosure is preferably fastened to both end pieces in such a way that the enclosure is closed tightly at the end pieces. To this end, the end piece has a metal ring, for example, to which the foil is fastened. In particular, the foil is fixedly connected to the ring along the entire periphery of the ring.

A method for producing the above-described piezoelectric component is also specified. The method comprises the following steps. A main body of the component and a structured foil are provided. The structured foil is wound around the main body.

The main body can be provided with a passivation material before the foil is wound onto the main body. The passivation material can be formed from the same material as the insulating material. The passivation material is preferably cured before the foil is applied.

An insulating material as described above is preferably applied to the foil.

The insulating material is preferably applied to the foil before the foil is wound around the main body. Here, at least one side of the foil can be provided with the insulating material in portions and may be free from the insulating material in portions. By way of example, an edge region of the foil intended for the outer region of the enclosure is free from insulating material, at least on one side. Instead, solder material can be applied to the edge region, such that the edge region can be soldered and the enclosure can therefore be sealed.

The insulating material can be cured before or after the winding of the foil. If the insulating material is cured once the foil has been wound on the man body, a particularly good form fit between the insulating material and the main body can be produced.

In one embodiment the insulating material can be applied to the foil before the structuring of the foil. The foil can then be structured three-dimensionally, and the insulating material can be cured. The insulating material thus contributes to the structuring of the foil.

Alternatively, the insulating material may only be applied to the foil following the structuring of the foil. By way of example, the insulating material is applied to the structured foil, and the foil provided with the insulating material is then wound around the main body. The insulating material is preferably molded integrally on the main body in such a way that no gaps, in particular no bubbles, are present in the enclosure.

Furthermore, further insulating material can be applied once the foil has been applied to the main body. In particular, an externally freely accessible outer face of the foil can be covered with insulating material.

The foil is preferably wound around the main body in low-pressure or vacuum conditions. In this case, a bubble-free application of the foil is possible in a particularly reliable manner.

Once the foil has been wound around the main body, the enclosure is preferably sealed outwardly. By way of example, further insulating material is introduced in an edge region of the foil for this purpose. A fastening region of the foil, which is arranged on the outermost edge region, is preferably free from insulating material and is fastened to a region of the foil arranged therebeneath. A seal, in particular in the lateral-side region of the enclosure, can thus be achieved. Furthermore, the enclosure can be connected to an end piece in order to seal the enclosure in a head or foot region of the component.

### BRIEF DESCRIPTION OF THE DRAWINGS

The subject matter described here will be explained in greater detail hereinafter on the basis of schematic exemplary embodiments, not shown to scale, in which:

FIG. 1 shows a side view of a piezoelectric component with an enclosure;

FIG. 2 shows a detail from a longitudinal section of the component from FIG. 1;

FIG. 3 shows a cross section of a piezoelectric component with a multi-layer enclosure;

FIG. 4 shows a detail of a longitudinal section of the enclosure of the component from FIG. 3;

FIG. 5 shows a longitudinal section of the component from FIG. 3;

FIG. 6 shows a cross section of a piezoelectric component with a multi-layer enclosure;

FIG. 7 shows a detail from the cross section from FIG. 6; and

FIG. 8 shows a structured foil, coated in portions, for producing an enclosure.

In the following figures, like reference signs preferably refer to functionally or structurally corresponding parts in the various embodiments.

### DETAILED DESCRIPTION OF ILLUSTRATIVE EMBODIMENTS

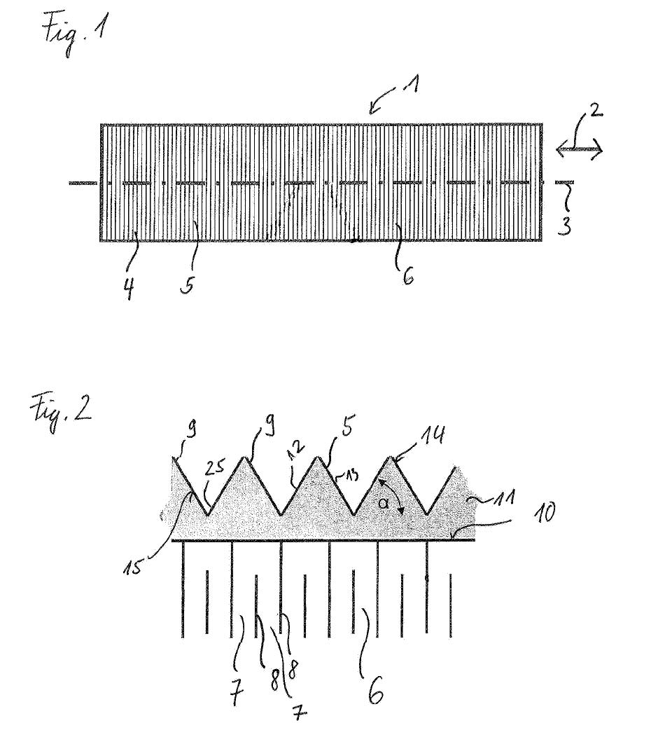

FIG. 1 shows a side view of a piezoelectric component 1.

The component 1 has a main body 6, which is surrounded by an enclosure 4. The main body 6, for example, has piezoelectric layers. The main body 6 is preferably formed as a monolithic sintered body. The enclosure 4 protects the main body 6 against the infiltration of moisture and harmful chemicals. By way of example, the component 1 is formed as a piezo actuator and is used to actuate an injection valve in a motor vehicle. In this case, the enclosure 4 protects the main body 6 preferably against chemicals contained in the fuel.

When a voltage is applied to the component 1, the component 1 expands along a direction of expansion 2. Here, the direction of expansion 2 is preferably the direction in which the component 1 expands to the greatest extent when a voltage is applied. By way of example, a valve is actuated as a result of the expansion of the component 1 in the direction of expansion 2.

The component 1 has a longitudinal axis 3, which in the present case coincides with the direction of expansion 2. The component 1 is preferably formed as a multi-layer component. By way of example, the component 1 has a plurality of piezoelectric layers, which are stacked one above the other along a stack direction. The stack direction preferably coincides with the direction of expansion 2.

The enclosure 4 has a structured foil 5. The foil 5 is preferably a metallic foil, for example, an aluminum foil. The foil 5 is helium-tight. In particular, the surface of the foil 5 is structured. The structuring is formed in such a way that excessively strong expansion stresses in the foil 5, which can form, for example, with an expansion of the component 1 in the direction of expansion 2, can be prevented. A tearing of the foil 5 is preferably prevented as a result of the structuring of the foil 5.

FIG. 2 shows a detail of a section through the component 1 from FIG. 1 along the longitudinal axis 3.

Piezoelectric layers 7 and electrode layers 8 are arranged above one another alternately in the main body 6 of the component 1. The electrode layers 8 are arranged alternately as far as an outer face 10 of the main body 6 and are distanced from the opposite outer face of the main body 6. For electric contacting of the electrode layers 8, base metallizations can be applied to the outer face 10 and to the opposite outer face, each base metallization being contacted with an electric connection of the component 1.

The foil 5 has elevations 9, which protrude from the outer face 10 and extend in a direction perpendicular to the longitudinal axis 3 of the component 1. The regions between the elevations 9 can be considered as indentations 25 in the foil 5. The elevations 9 provide the foil 5 with a ribbed surface structure. In particular, the elevations 9 are formed as ribs, which run perpendicularly to the longitudinal axis 3 and parallel to the outer face 10. Each elevation 9 has two opposed surface regions 12, 13, which are flank-like. Each surface region 12, 13 is arranged at an aperture angle α to the outer face 10. The aperture angle α is preferably selected in such way that, if expansion forces occur along the direction of expansion 2, merely the aperture angle α of the foil 5 is changed, and greater stresses do not occur in the foil 5. It has been found that, here, an aperture angle in the range from 40° to 60°, in particular in a range from 40° to 55°, is particularly favorable.

Instead of the rib structure of the foil 5 shown in FIGS. 1 and 2, other structures are also possible. By way of example, the foil 5 can be structured in such a way that expansion forces or compression forces running in different directions can be taken up by a deformation of the foil 5, for example, forces running in the direction of the longitudinal axis 3 and in a direction perpendicular to the longitudinal axis 3. By way of example, the foil 5 has an eggcup structure. In particular, the foil 5 may have partially spherical elevations, for example, semi-spherical elevations. The elevations may also be flattened here, at least in part. The elevations are preferably rotationally symmetrical, in particular rotationally symmetrical with respect to an axis of rotation that extends perpendicularly to the outer face 10, above which the foil 5 is arranged.

An insulating material 11, in particular an electrically insulating material 11, is arranged between the foil 5 and the outer face 10 of the main body 6. By way of example, the insulating material 11 comprises an organic material. The insulating material 11 is preferably formed in such a way that expansion peaks, which may occur with a formation of cracks in the main body 6, are not transmitted directly to the foil 5, but are distributed by the insulating material 11. The insulating material 11 preferably reduces the expansion forces occurring at the foil 5. The insulating material 11 is preferably resilient.

The insulating material 11 is applied to a side 15 of the foil 5 facing the main body 6. The insulating material 11 is adjacent to the foil 5 and the outer face 10 of the main body 6, in particular the piezoelectric layers 7. The insulating material 11 preferably completely fills the region between the foil 5 and the outer face of the main body 6. The insulating material 11 may additionally also be applied to a side 14 facing away from the main body 6.

By way of example, the insulating material 11 is applied to the structured foil 5 before the foil 5 is arranged on the main body 6. The insulating material 11 can be applied in uncured form to the structured foil 5 and can cure on the foil 5. The material 11 can thus adapt to the structuring of the foil 5. Once cured, the foil 5 can be wound around the main body 6, for example, in a low-pressure or vacuum environment. Air bubbles are thus preferably prevented from forming between the foil 5 and the outer face 10 of the main body 6.

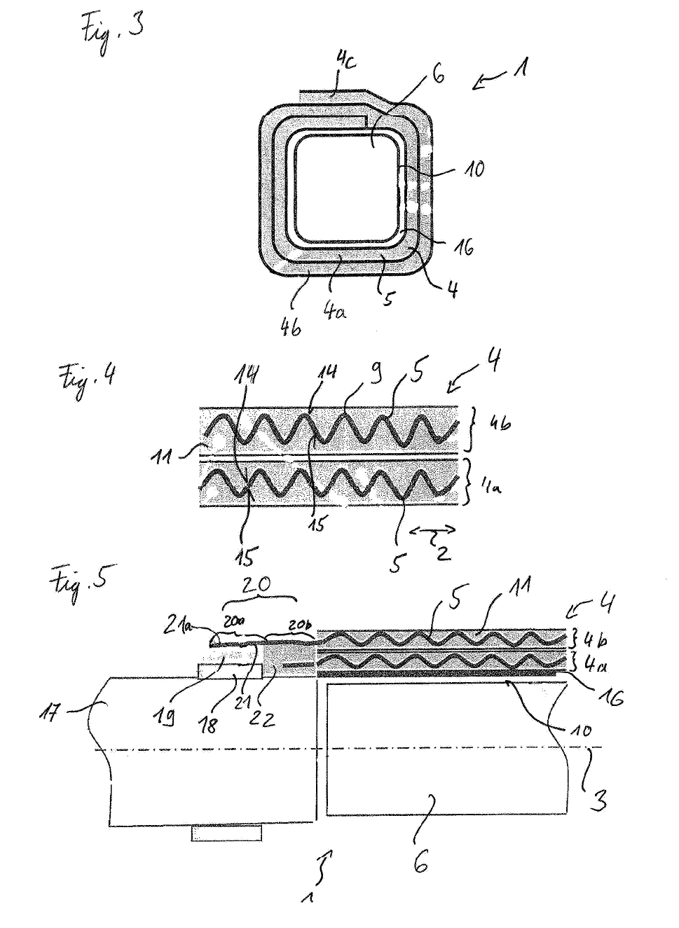

FIG. 3 shows a cross section of a piezoelectric component with a multi-layer enclosure 4. FIG. 4 shows a detail of a longitudinal section of the multi-layer enclosure 4 from FIG. 3.

The multi-layer enclosure 4 has a structured foil 5, which can be seen in detail in FIG. 4. The foil 5 is structured in an undulating manner and has elevations 9, which, similarly to the elevations 9 in FIG. 2, are expanded three-dimensionally perpendicularly to the longitudinal axis 3 of the component 1. The foil 5 is wound a number of times around the main body 6. The enclosure 4 thus has a first layer 4a, which is wound directly onto a passivation 16 of the main body 6, and a second layer 4b, which is arranged above the first layer 4a. In an end region the foil has a third outermost layer 4c, which is wound over the second layer 4b and is connected, preferably fixedly, to the second layer 4b.

As can be seen in FIG. 4, the layers 4a, 4b comprise the foil 5. The foil 5 is embedded in the insulating material 11. In particular, the insulating material 11 is applied to the foil both in the first layer 4a and in the second layer 4b on a side 14 facing away from the main body 6 and on a side 15 facing the main body 6.

The multi-layer enclosure 4 can be produced as follows. An unstructured foil 5 is provided and is then structured, in particular undulated.

An insulating material 11 is then applied to both sides 14, 15 of the structured foil 5. Alternatively, the insulating material 11 can already be applied, at least in part, to the foil 5 before the structuring of the foil 5. By way of example, the insulating material 11 is applied to one side of the foil 5, and the foil 5 is then structured. Insulating material 11 is then also applied to the other side of the foil 5.

The insulating material 11 is preferably applied to the foil 5 in such a way that a planar surface of the enclosure 4 is produced. In particular, the insulating material 11 can fill the indentations of the structured foil 5.

By way of example, the insulating material 11 arranged on the side 14 of the foil 5 facing away from the main body 6 is dimensionally stable, such that the structuring of the foil 5 is maintained. By way of example, the insulating material 11 arranged on the side 14 facing away from the main body 6 is applied to the foil 5 before the structuring of the foil 5. The insulating material 11 applied to the side 15 of the foil 5 facing the main body 6 is preferably deformable, such that, as the foil 5 is applied to the main body, the insulating material 11 can adapt to the substrate. Different insulating materials may also be used. By way of example, a material different from that used for the side 15 facing the main body 6 can be used for the side 14 of the foil 5 facing away from the main body 6.

The foil 5 provided with the insulating material 11 is now wound a number of times, for example, twice, around the main body 6. Due to the planar surfaces of the layers 4a, 4b, air bubbles can be prevented from forming in the enclosure 4.

Once the foil has been wound around completely, the enclosure 4 is preferably sealed, such that no moisture can infiltrate the enclosure 4. By way of example, the outermost layer 4c of the enclosure is bonded or soldered to a layer 4b arranged therebeneath. The insulating material is then dried or cured.

A further enclosure, for example, a further layer, can be applied to the outer face of the enclosure 4 in order to attain additional protection of the component 1. By way of example, the further enclosure is formed as a heat shrink tube.

FIG. 5 shows a longitudinal section of the component 1 from FIG. 3 and in particular a fastening of the enclosure 4 to an end piece 17 of the component 1. The end piece 17, for example, comprises a ceramic material, in particular a sintered ceramic material. The end piece 17 is used, for example, to hold the main body 6 and/or to electrically insulate the main body 6. Furthermore, electric connections of the component 1 can be provided in the end piece 17. By way of example, the component 1 has end pieces 17 of this type, for example, a head part and a foot part, at both longitudinal-side ends of the main body 6. The end pieces can be adhesively bonded to the main body 6.

A fastening means for fastening the enclosure 4 and in particular for sealing the enclosure 4 is provided on the end piece 17. The fastening means is formed here as a metal ring 18, which surrounds the end piece 17 annularly. The metal ring 18 is sintered to the end piece 17, for example.

The enclosure 4 has an edge region 20 protruding beyond the main body 6. The foil 5 is unstructured in the edge region 20. The edge region 20 has a fastening region 20a, in which the foil 5 is fastened to the metal ring 18, for example, is connected to the metal ring 18 by means of a soldered joint 19.

By way of example, the enclosure 4 of the main body 6 is produced in the following way.

The end piece 17 provided with the metal ring 18 is fastened to the main body 6. A passivation material 16 is then applied to the main body 6.

A structured foil 5 provided with an insulating material 11 is provided. Here, the foil 5 is preferably free from insulating material 11 in an edge region 21 forming the longitudinal-side edge region 20 of the enclosure 4. Instead, a solder material and a flux are applied in a fastening region 21a of the edge region 21 arranged at the outermost edge in order to produce the soldered joint 19. By way of example, this fastening region 21a of the foil 5 is between 2 mm and 5 mm wide.

The foil 5 is then wound around the main body 6 and around part of the end piece 17 in such a way that the edge region 21 of the foil winds around a region of the end piece 17. Here, the fastening region 21a of the foil 5 coated with solder material 19 comes to rest above the metal ring 18.

A cavity, which may or may not be provided, in an intermediate region 20b of the edge region 20 of the enclosure 4 arranged on the end piece 17 at the border to the main body 6 is then filled with a deformable sealing compound 22. The sealing compound 22 can be formed similarly to the insulating material 11. The cavity is preferably filled completely. The foil 5 is then molded integrally to the sealing compound 22 at low pressure, in particular in vacuum conditions, in a bubble-free manner.

Lastly, the foil 5 is soldered in the fastening region 21a thereof to the metal ring 18, for example, in a reflow soldering process. A tight and peripheral connection between the enclosure 4 and the end piece 17 is thus produced.

The component 1 may also have electric connections (not illustrated) for electrical contact of the component 1. The connections are preferably guided through the end piece 17. In particular, the connections can be connected to a base metallization on the outer face 10 of the main body 6 and may lead along the outer face 10 under the passivation 16 to the end piece 17. The end piece 17 preferably has a bore, through which the connections are guided outwardly through the end piece 17. The bore preferably leads through a region of the end piece 17 surrounded by the metal ring 18 and thus allows the connections to be guided outwardly through the interior of the end piece 17 without having to interrupt the enclosure 4, in particular the connection between the foil 5 and the metal ring 18. A particularly tight enclosure 4 can thus be achieved.

The component is preferably provided with two end pieces 17, in particular a head part and a foot part, wherein the enclosure 4 is fastened to both end pieces 17 as described previously.

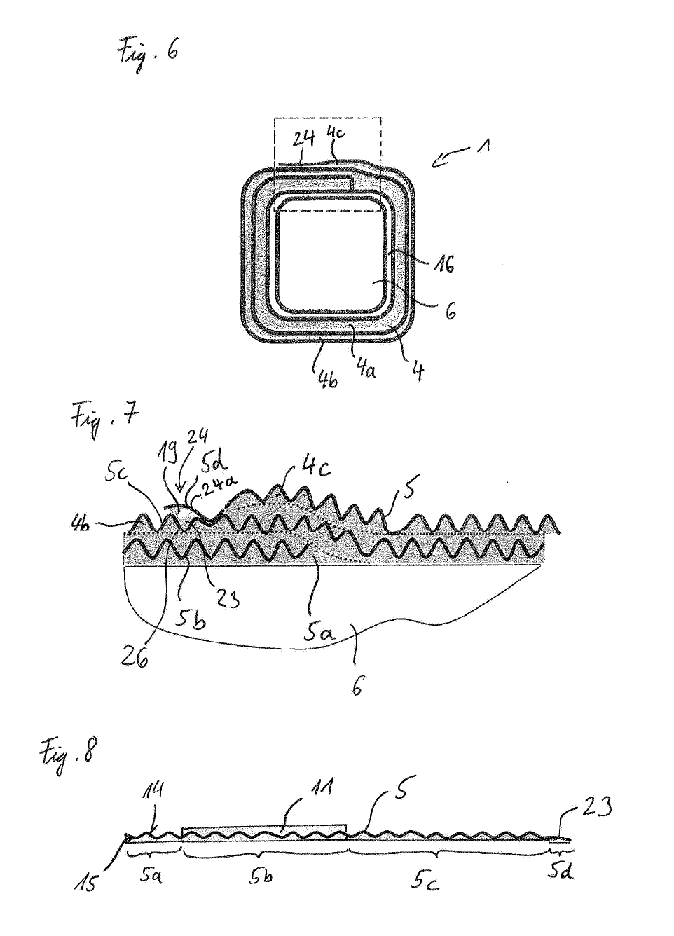

FIG. 6 shows a cross section of a piezoelectric component 1 with a multi-layer enclosure 4 and in particular a seal of the enclosure 4 on the outer lateral surface thereof.

In particular, a lateral-side edge region 24 of the foil 5 is connected continuously and fixedly in the outermost layer 4c of the enclosure 4 to the second layer 4b arranged therebeneath. A sealing of this type may also be provided with the enclosure 4 shown in the previous figures.

FIG. 7 shows a detail of the component 1 from FIG. 6 in the region bordered by a dashed line in FIG. 6.

FIG. 8 shows a structured foil 5 that can be used to produce the enclosure 4 shown in FIGS. 6 and 7.

As can be seen in FIG. 8, an edge starting portion 5a of the foil 5, which is applied to the main body 6, is provided on just one side with the insulating material 11. In particular, the insulating material 11 is applied only to the side 15 facing the main body. As the foil is wound around the main body 6, an application of the second layer 4b to the first layer 4a is thus facilitated.

A further foil portion 5b, which adjoins the starting region 5a, is provided on both sides 14, 15 with the insulating material 11. The first layer 4a of the enclosure 4 is formed from this foil portion 5b, together with the starting portion 5a (see FIG. 7).

A further foil portion 5c adjoins the foil portion 5b coated on both sides and is provided on just one side with the insulating material 11. The second layer 4b is formed substantially from this foil portion 5c (see FIG. 7). The foil portion 5c is provided with insulating material 11 just on the side 15 facing the main body 6. The side 14 facing away from the main body 6 is free from insulating material. A fastening, in particular a soldering, of the lateral-side edge region 24 of the foil 5 (see FIG. 6) on the outer face of this foil portion 5c is thus made possible.

An end portion 5d adjoins the foil portion 5c provided on one side with insulating material 11. The end portion 5d is free from insulating material on both sides and forms the lateral-side edge region 24 (see FIG. 6). The end portion 5d is provided with solder material 23 and a flux for a reflow soldering process before the application of the foil 5 to the main body 6. The end portion 5c is between 2 and 5 mm long, for example.

To form the enclosure 4, the structured foil 5, which is coated in portions, shown in FIG. 8 is wound around the main body 6 starting with the starting portion 5a coated on one side. Here, the side 15 provided with insulating material 11 points toward the main body 6. The winding process is preferably performed in low-pressure or vacuum conditions.

Once the foil 5 is wound completely around the main body 6, the uncoated side of the foil portion 5c and of the end portion 5d points outwardly. The end portion 5d is then connected fixedly to the foil portion 5c arranged therebeneath. In particular, the end portion 5d is soldered to the uncoated outer face of the foil portion 5c, such that a soldered connection 19 is produced (see FIG. 7). The end portion 5d thus forms a lateral-side fastening region 24a of the foil 5, which is fastened to a further region 26 of the foil 5 arranged therebeneath.

An overlap region, which might not be soldered in the fastening region 5c of the foil to the foil portion 5b arranged therebeneath, is preferably molded integrally in a bubble-free manner to the layer 4b arranged therebeneath, such that no bubbles remain in the enclosure 4.

In a further step the side of the structured foil 5 externally accessible is preferably provided with a coating, in particular with an organic coating. A smooth surface of the enclosure 4 can thus be obtained. The coating can be formed similarly to the insulating material 11.

In a preferred embodiment the enclosure 4 is sealed both in its longitudinal-side edge regions 21 and on the outer lateral surface of the main body 6, preferably as shown in FIGS. 5 and 7.

1-15. (canceled)

16. A piezoelectric component comprising:
an enclosure comprising a structured foil; and
a main body surrounded at least in part by the enclosure in order to protect the main body.

17. The piezoelectric component according to claim 16, wherein the foil has at least one indentation or elevation.

18. The piezoelectric component according to claim 17, wherein the main body has a direction of expansion, and wherein the indentation or elevation extends perpendicularly to the direction of expansion.

19. The piezoelectric component according to claim 17, wherein the foil comprises a plurality of indentations or elevations.

20. The piezoelectric component according to claim 16, wherein the structuring of the foil is formed in such a way that mechanical stresses in the foil are kept low.

21. The piezoelectric component according to claim 16, wherein the foil is wound around the main body.

22. The piezoelectric component according to claim 21, wherein the foil is wound a number of times around the main body.

23. The piezoelectric component according to claim 16, wherein at least one surface region of the foil is arranged at an angle between 40° and 60° to an outer face of the component.

24. The piezoelectric component according to claim 16, further comprising an electrically insulating material arranged on at least one side of the foil.

25. The piezoelectric component according to claim 24, wherein the insulating material is arranged on a side of the foil facing the main body.

26. The piezoelectric component according to claim 25, wherein the insulating material completely fills a space between the foil and the main body.

27. The piezoelectric component according to claim 24, wherein the insulating material is arranged on a side of the foil facing away from the main body.

28. The piezoelectric component according to claim 16, wherein the foil has a fastening region, which is arranged above a further region of the foil and is fastened to this region.

29. The piezoelectric component according to claim 16, wherein the component has at least one end piece arranged at an end of the main body, wherein the enclosure is fastened to the end piece.

30. A method for producing a piezoelectric component, the method comprising:
providing a main body of a component;
providing a structured foil; and
winding the structured foil around the main body to form an enclosure that surrounds at least a part of the main body to protect the main body.
